(19) United States
(12) Patent Application Publication
(10) Pub. No.: US 2017/0026008 A1
(43) Pub. Date: Jan. 26, 2017

(54) PROTECTION CIRCUIT OF POWER AMPLIFICATION CIRCUIT AND POWER AMPLIFICATION CIRCUIT USING THE SAME

(71) Applicant: SAMSUNG ELECTRO-MECHANICS CO., LTD., Suwon-si (KR)

(72) Inventors: Kyung Hee HONG, Suwon-si (KR); Hyeon Seok HWANG, Suwon-si (KR); Jeong Hoon KIM, Suwon-si (KR)

(73) Assignee: SAMSUNG ELECTRO-MECHANICS CO., LTD., Suwon-si (KR)

(21) Appl. No.: 15/052,247

(22) Filed: Feb. 24, 2016

(30) Foreign Application Priority Data
Jul. 20, 2015 (KR) 10-2015-0102319

(51) Int. Cl. H03F 1/52; H03F 3/21; H03F 3/19

(52) U.S. Cl. CPC H03F 1/52; H03F 3/19; H03F 3/211; H03F 2200/451; H03F 2200/555

(57) ABSTRACT

A protection circuit of a power amplifier includes a first current mirror configured to supply a current mirrored to a first reference current as a bias current of a driver amplifier; and a current sink configured to adjust a bias current of the driver amplifier by sinking the first reference current according to a magnitude of a voltage output from the power amplifier.

### CROSS-REFERENCE TO RELATED APPLICATION(S)

This application claims the benefit under 35 U.S.C. §119(a) of Korean Patent Application No. 10-2015-0102319, filed on Jul. 20, 2015 in the Korean Intellectual Property Office, the entire disclosure of which is incorporated herein by reference for all purposes.

### BACKGROUND

1. Field

The following description relates to protection of a power amplification circuit.

2. Description of Related Art

In general, various electronic devices operate by being embedded in a terminal such as a cellular phone, a smart phone, a personal digital assistant (PDA), a radio frequency identification (RFID) apparatus, etc. and are configured as a communications module integrated on a printed circuit board (PCB).

A power amplifier circuit is provided in such a communications module and is used to amplify an RF signal input from a transceiver of the terminal.

However, in a case where a voltage of an output signal of such a power amplifier circuit abnormally increases, performance of a driving amplifier or a power amplifier included in the power amplifier circuit deteriorates or is damaged. Thus, a protection circuit for protecting the power amplifier module is necessary.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect a protection circuit of a power amplifier, the protection circuit includes a first current mirror configured to supply a current mirrored to a first reference current as a bias current of a driver amplifier; and a current sink configured to adjust the bias current of the driver amplifier by sinking the first reference current according to a magnitude of a voltage output from the power amplifier.

The current sink may include a diode circuit including a diode electrically connected according to the magnitude of the voltage output; a resistor connected in series to the diode circuit; and a transistor connected in parallel to both ends of the resistor and configured to sink the first reference current according to a magnitude of voltages applied to both ends of the resistor.

A magnitude of the sunk first reference current may increase in an exponential manner in proportion to the magnitude of the voltage output from the power amplifier.

The protection circuit may further include a second current mirror configured to supply a current mirrored to a second reference current as a bias current of the power amplifier that amplifies the RF signal having the adjusted gain by the driver amplifier.

The protection circuit may further include a third current mirror configured to add a current mirrored to the second reference current to the bias current supplied to the driver amplifier.

A magnitude of the current mirrored to the second reference current added to the bias current supplied to the driver amplifier may less than the bias current supplied to the driver amplifier, and may be a magnitude substantially preventing oscillation of the power amplifier.

According to another general aspect, a power amplification circuit includes a driver amplifier configured to adjust a gain of an RF signal; a first current mirror configured to supply a current mirrored to a first reference current as a bias current of the driver amplifier; and a current sink configured to adjust the bias current of the driver amplifier by sinking the first reference current according to a determined characteristic of an output from the power amplification circuit.

The current sink may include a diode circuit including one or more diodes electrically connected according to the magnitude of the voltage output from the power amplification circuit; a resistor connected in series to the diode circuit; and a transistor connected in parallel to both ends of the resistor and configured to sink the first reference current according to magnitude of voltages applied to both ends of the resistor.

A magnitude of the sunk first reference current may be a value that increases in an exponential manner in proportion to the magnitude of the voltage output from the power amplification circuit.

The power amplification circuit may further include a power amplifier configured to amplify the RF signal having the adjusted gain by the driver amplifier; and a second current mirror configured to supply a current mirrored to a second reference current as a bias current of the power amplifier.

The power amplification circuit of claim 10, further comprising: a third current mirror configured to add the current mirrored to the second reference current with the bias current supplied to the driver amplifier.

A magnitude of the current mirrored to the second reference current added with the bias current supplied to the driver amplifier may be a value smaller than the bias current supplied to the driver amplifier and may have an adaptively established magnitude to prevent substantial oscillation of the power amplification circuit.

The driver amplifier may be configured to adaptively adjust the gain of the RF signal according to the determined characteristic of the output of the power amplification circuit.

The driver amplifier may be configured to adaptively adjust the gain of the RF signal according to the determined characteristic of the output of the power amplifier.

The current sink may be configured to adaptively adjust the bias current of the driver amplifier by sinking the first reference current according to the determined characteristic of the output from the power amplification circuit, and wherein the determined characteristic may be a magnitude of a voltage.

Other features and aspects will be apparent from the following detailed description, the drawings, and the claims.

### BRIEF DESCRIPTION OF THE DRAWINGS

The above and other aspects, features, and advantages of the present disclosure will be more clearly understood from the following detailed description taken in conjunction with the accompanying drawings, in which:

FIG. 1 is a diagram of a configuration of a power amplification circuit including protection circuits, according to a first embodiment.

FIGS. 2A through 2D are waveform diagrams of a portion of the power amplification circuit.

FIG. 3 is a diagram of a configuration of a power amplification circuit including protection circuits, according to a second embodiment.

FIGS. 4A and 4B are diagrams for comparing stability factor of the power amplification circuits of the first and second embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Various embodiments will now be described in detail with reference to the accompanying drawings.

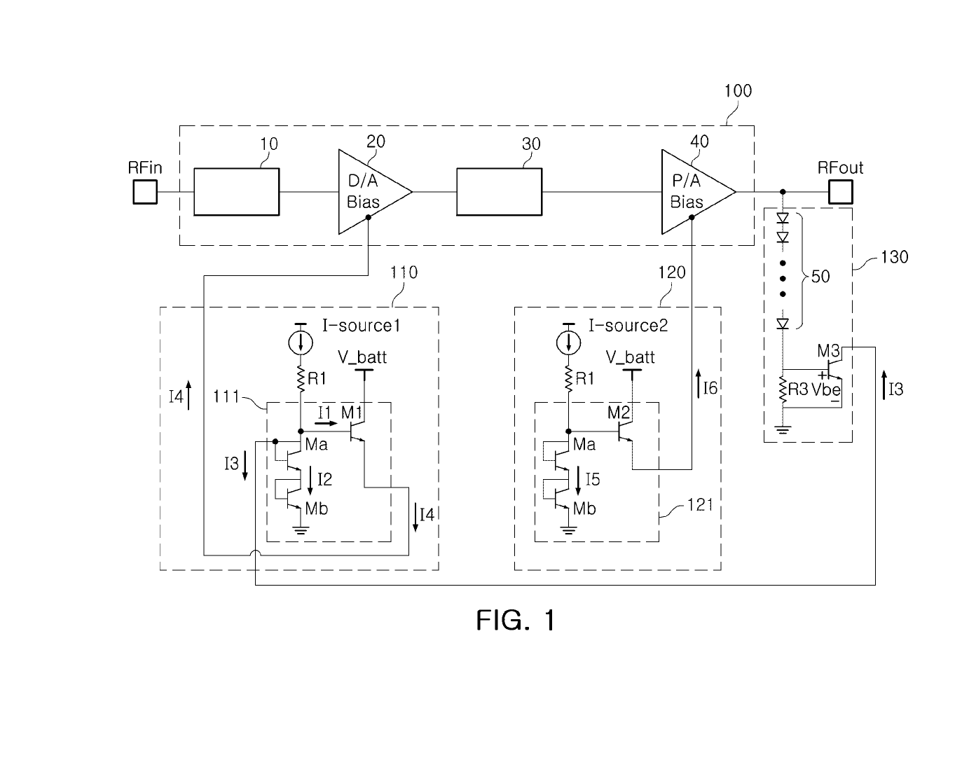

FIG. 1 is a diagram of a configuration of a power amplification circuit 100 including protection circuits 110 through 130, according to a first embodiment.

The power amplification circuit 100 including the protection circuits 110 through 130 according to the first example embodiment will be described in detail with reference to FIG. 1 below.

As shown in FIG. 1, the power amplification circuit 100 includes a driver amplifier (DA) 20 that adjusts a gain of an RF signal input through an input end RFin and a power amplifier (PA) 40 that amplifies the RF signal having the adjusted gain. The amplified RF signal is output through an output end RFout.

Meanwhile, the power amplification circuit 100 further includes an input matching unit 10 that is provided between the input end RFin and the driver amplifier 20 and compensates for loss of the RF signal and an intermediate matching unit 30 that is provided between the driver amplifier 20 and the power amplifier 40 and matches impedance between the driver amplifier 20 and the power amplifier 40.

The protection circuits 110 through 130, according to the first embodiment, include a first bias supply circuit 110, a second bias supply circuit 120, and a current sink 130.

Among the protection circuits 110 through 130, the first bias supply circuit 110 may supply a bias current I4 to the driver amplifier 20 of the power amplification circuit 100.

In more detail, the first bias supply circuit 110 includes a first current source I-source1, a first voltage V_batt, and a first current mirror 111. The first current mirror 111 generates a first reference current I2 by using the first current sourceI-source1, and supplies the current I4 mirrored to the first reference current I2 as a bias current of the driver amplifier 20. The mirrored current I4 is a value obtained by multiplying a predetermined amplification rate to the current I1 input to a base of a transistor M1.

A current I3 is a current sunk to the current sink 130 during operations of the protection circuits 110 through 130 and will be described later.

The above-described first current mirror 111 is configured by connecting in series two transistors Ma and Mb, in which a base and a collector are connected to each other, and connecting a collector of an upper transistor Ma and the base of the other transistor M1. Meanwhile, a resistor R1 may be used to prevent noise.

Furthermore, among the protection circuits 110 through 130, the second bias supply circuit 120 supplies a bias current I6 to the power amplifier 40 of the power amplification circuit 100.

The second bias supply circuit 120 includes a second current source I-source2, a second voltage V_batt, and a second current mirror 121. The second current mirror 121 may generate a second reference current I5 by using the second current source I-source2, and may supply the current I6 mirrored to the second reference current I5 as a bias current of the power amplifier 40. The mirrored current I6 may be a value obtained by multiplying a predetermined amplification rate to a current input to a base of a transistor M2.

The above-described second current mirror 121 is configured by connecting in series the two transistors Ma and Mb in which the base and the collector are connected to each other and connecting the collector of the upper transistor Ma and the base of the other transistor M2. The resistor R1 may be used to prevent noise, and may be omitted in certain configurations.

The current sink 130 sinks the bias current I4 supplied to the driver amplifier 20 according to magnitude of a voltage output from the power amplification circuit 100.

In more detail, the current sink 130 includes a diode circuit 50 including one or more diodes electrically connected (for example, with n diodes in a serial arrangement, parallel arrangement, or array structure) according to the magnitude of the voltage output from the power amplification circuit 100, a resistor R3 in series connected to the diode circuit 50, and a transistor M3 that is connected in parallel to both ends of the resistor R3 and configured to sink the first reference current I2 according to a magnitude of voltages applied to both ends of the resistor R3 and thus adjusts magnitude of the bias current I4 of the driver amplifier 20. A base of the transistor M3 is connected to one end of the resistor R3, and an emitter thereof is connected to another end of the resistor R3.

An example operation of the above-described current sink 130 will be described below.

If the voltage output from the power amplification circuit 100 exceeds a predetermined voltage, the diode circuit 50 including the one or more diodes may be electrically connected, and the voltages may be applied to both ends of the resistor R3, i.e., between the base and the emitter of the transistor M3. In this regard, the current I3 flowing through the transistor M3 may be a current that increases in an exponential manner in proportion to a magnitude of a voltage between the base and the emitter of the transistor M3 as shown in Equation 1 below,

I3∝exp(Vbe) [Equation 1]

where I3 denotes the current flowing through the transistor M3 and Vbe denotes the voltage between the base and the emitter of the transistor M3.

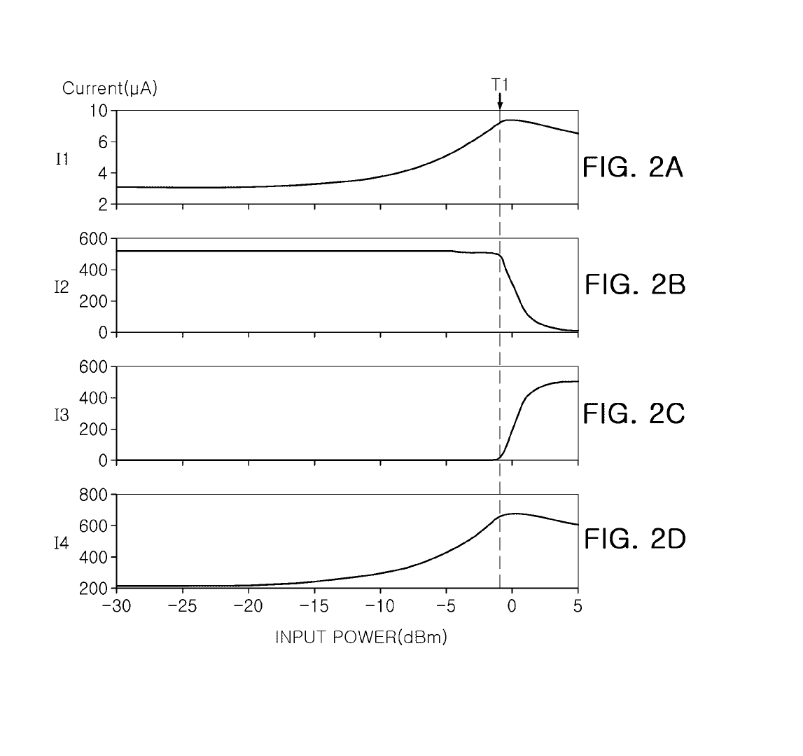

FIGS. 2A through 2D are waveform diagrams of a portion of the first embodiment, in which an X axis shows input power (unit: dBm) input to the input end RFin of the power amplification circuit 100 and a Y axis shows the current I1 (FIG. 2A), the current I2 (FIG. 2B), the current I3 (FIG. 2C), and the current I4 (FIG. 2D).

As shown in FIGS. 1 and 2, when the input power input to the input end RFin is gradually increased, the protection circuits 110 through 130 operates at a time T1 in which the voltage output from the power amplification circuit 100 exceeds the predetermined voltage. Thus, because the reference current I2 of the first current mirror (111 of FIG. 1) is reduced from the time T1, the current I4 mirrored to the reference current I2 is reduced, while the current I3 sunk to the current sink (130 of FIG. 1) is increased instead.

As described above, according to the example embodiment, the magnitude of the bias current supplied to the driver amplifier 20 that adjusts the gain of the RF signal may be reduced according to the magnitude of the voltage output from the power amplification circuit 100, thereby protecting the power amplification circuit 100 from an overvoltage.

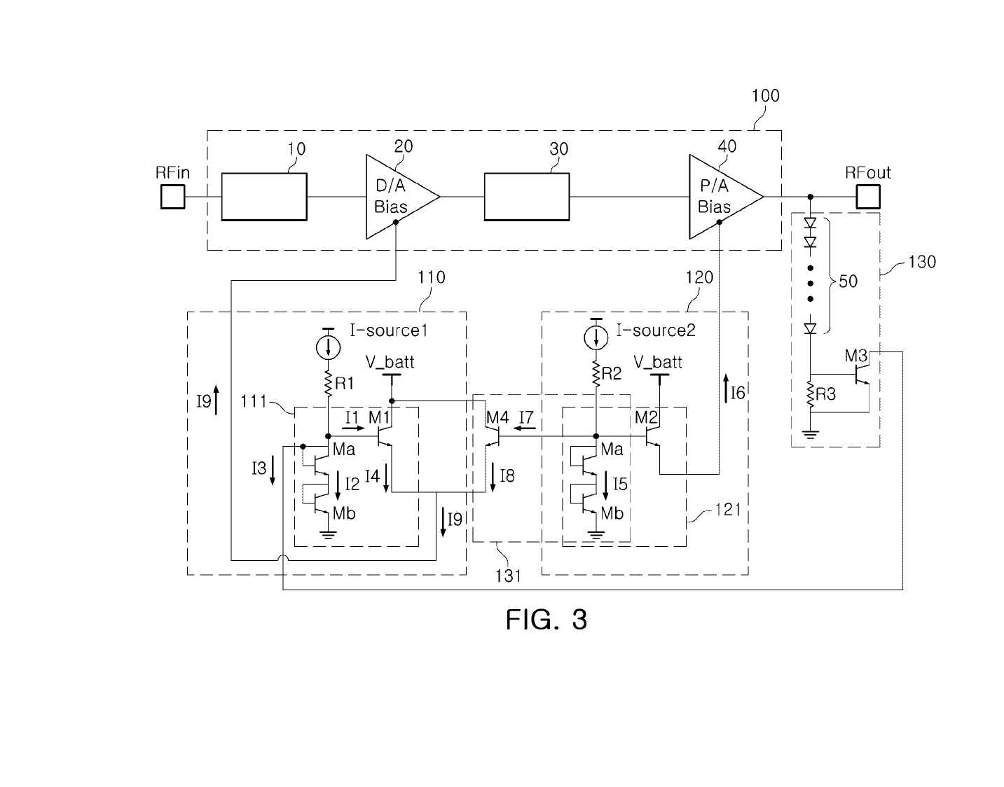

FIG. 3 is a diagram of a configuration of the power amplification circuit 100 including the protection circuits 110 through 130, according to a second embodiment. The power amplification circuit 100 further includes a third current mirror 121 that adds a current I8 mirrored to the second reference current I5 to the given bias current I4 supplied to the driver amplifier 20, compared to the power amplification circuit 100 according to the example embodiment of FIG. 1. The above-described current I8 mirrored to the second reference current I5 may be a value obtained by multiplying a predetermined amplification rate to a current I7 input to a base of a transistor M4.

To this end, the transistor M4 is further included in the power amplification circuit 100, and is configured by connecting the base of the transistor M4 to a collector of the upper transistor Ma among the two transistors Ma and Mb of the second current mirror 121, and respectively connecting an emitter and a collector of the transistor M4 to an emitter and a collector of the transistor M1 of the first current mirror 111.

The protection circuits 110 through 130, according to the second embodiment described with reference to FIG. 3 above, are used to supplement the protection circuits 110 through 130 according to the example embodiment of FIG. 1.

In more detail, in a case in which a magnitude of a voltage output from the power amplifier module 100 increases abnormally, the protection circuits 110 through 130 of FIG. 1 operates, and the current I3 sunk to the current sink (130 of FIG. 1) is increased (FIG. 2C), while the reference current I2 of the first current mirror (111 of FIG. 1) is reduced (FIG. 2B).

Since the reference current I2 of the first current mirror (111 of FIG. 1) is reduced, the bias current I4 supplied to the driver amplifier 20 may be also be reduced (FIG. 2D). In a case in which the bias current I4 is continuously reduced, oscillation of the power amplification circuit 100 may occur at a specific time. The above-described specific time may be different according to a design condition of the power amplification circuit 100. The oscillation may also occur at a time when the bias current I4 is 0 or a value exceeding 0.

Therefore, as shown in FIG. 3, the third current mirror 131 may be additionally configured, and a bias current I9 may be supplied to the driver amplifier 20 by adding the bias current I8 to the given bias current I4 in such a manner that no oscillation occurs, thereby preventing oscillation from occurring in the power amplification circuit 100.

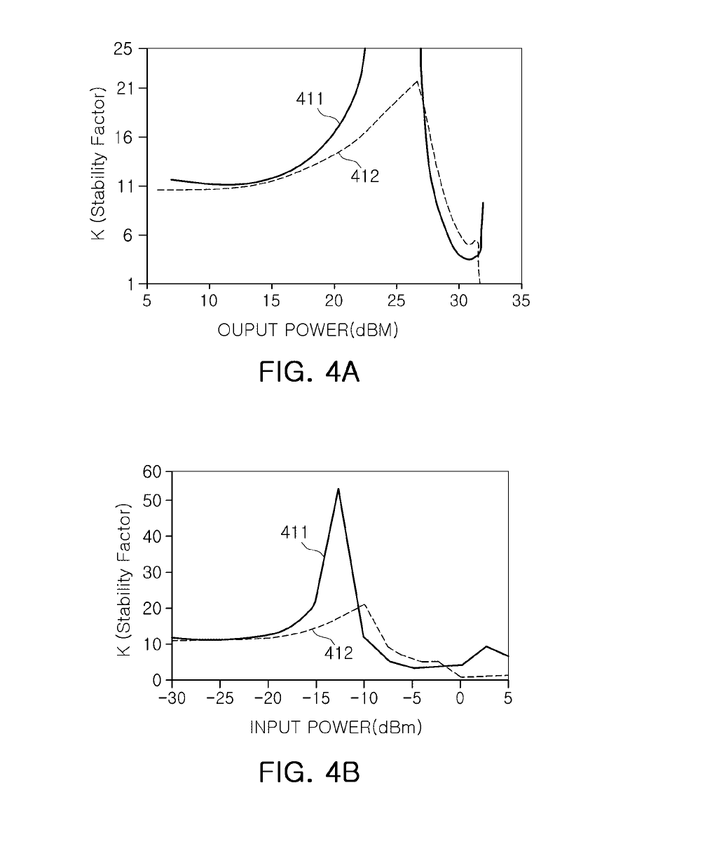

FIGS. 4A and 4B are diagrams for comparing stability factor K of the power amplification circuit 100 of the first embodiment 412 and the second embodiment 411. FIG. 4A shows the stability factor K with respect to output power (X axis) according to the first embodiment 412 and second embodiment 411. FIG. 4B shows the stability factor K with respect to input power (X axis) according to the first embodiment 412 and second embodiment 411.

As shown in FIGS. 4A and 4B, in the first embodiment 412, the stability factor K is reduced below 1 in a specific section of the output power and the input power, whereas in the second embodiment 411, the stability factor K exceeds 1 in all sections of the output power and the input power, which substantially prevents unwanted oscillation.

As described above, the bias supply circuit of the power amplifier supplies the bias current capable of substantially preventing oscillation to the driver amplifier, and thus the oscillation may be prevented, thereby protecting the power amplification circuit.

A hetero-junction bipolar transistor (HBT) may be employed, however, any other transistor or other device suitable for high frequency and high output may be used.

As set forth above, according to example embodiments, a magnitude of bias current supplied to the driver amplifier that adjusts a gain of an RF signal is reduced according to a magnitude of voltage output from the power amplification circuit 100, thereby protecting the power amplification circuit 100 from an overvoltage.

The bias supply circuit of the power amplifier supplies a bias current capable of substantially preventing deleterious oscillation to the driver amplifier, and thus the oscillation may be effectively prevented, thereby protecting the power amplification circuit.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A protection circuit of a power amplifier, the protection circuit comprising:
a first current mirror configured to supply a current mirrored to a first reference current as a bias current of a driver amplifier; and
a current sink configured to adjust the bias current of the driver amplifier by sinking the first reference current according to a magnitude of a voltage output from the power amplifier.

2. The protection circuit of claim 1, wherein the current sink includes:
a diode circuit including a diode electrically connected according to the magnitude of the voltage output;
a resistor connected in series to the diode circuit; and
a transistor connected in parallel to both ends of the resistor and configured to sink the first reference current according to a magnitude of voltages applied to both ends of the resistor.

3. The protection circuit of claim 1, wherein a magnitude of the sunk first reference current increases in an exponential manner in proportion to the magnitude of the voltage output from the power amplifier.

4. The protection circuit of claim 1, further comprising:
a second current mirror configured to supply a current mirrored to a second reference current as a bias current of the power amplifier that amplifies an RF signal having an adjusted gain by the driver amplifier.

5. The protection circuit of claim 4, further comprising:
a third current mirror configured to add a current mirrored to the second reference current to the bias current supplied to the driver amplifier.

6. The protection circuit of claim 5, wherein a magnitude of the current mirrored to the second reference current added to the bias current supplied to the driver amplifier is less than the bias current supplied to the driver amplifier, and is a magnitude substantially preventing oscillation of the power amplifier.

7. A power amplification circuit, comprising:
a driver amplifier configured to adjust a gain of an RF signal;
a first current mirror configured to supply a current mirrored to a first reference current as a bias current of the driver amplifier; and
a current sink configured to adjust the bias current of the driver amplifier by sinking the first reference current according to a determined characteristic of an output from the power amplification circuit.

8. The power amplification circuit of claim 7, wherein the current sink comprises:
a diode circuit including one or more diodes electrically connected according to the magnitude of the voltage output from the power amplification circuit;
a resistor connected in series to the diode circuit; and
a transistor connected in parallel to both ends of the resistor and configured to sink the first reference current according to magnitude of voltages applied to both ends of the resistor.

9. The power amplification circuit of claim 7, wherein a magnitude of the sunk first reference current is a value that increases in an exponential manner in proportion to the magnitude of the voltage output from the power amplification circuit.

10. The power amplification circuit of claim 7, further comprising:
a power amplifier configured to amplify the RF signal having the adjusted gain by the driver amplifier; and
a second current mirror configured to supply a current mirrored to a second reference current as a bias current of the power amplifier.

11. The power amplification circuit of claim 10, further comprising: a third current mirror configured to add the current mirrored to the second reference current with the bias current supplied to the driver amplifier.

12. The power amplification circuit of claim 11, wherein a magnitude of the current mirrored to the second reference current added with the bias current supplied to the driver amplifier is a value smaller than the bias current supplied to the driver amplifier and has an adaptively established magnitude to prevent substantial oscillation of the power amplification circuit.

13. The power amplification circuit of claim 7, wherein the driver amplifier is configured to adaptively adjust the gain of the RF signal according to the determined characteristic of the output of the power amplification circuit.

14. The power amplification circuit of claim 10, wherein the driver amplifier is configured to adaptively adjust the gain of the RF signal according to the determined characteristic of the output of the power amplifier.

15. The power amplification circuit of claim 13, wherein the current sink is configured to adaptively adjust the bias current of the driver amplifier by sinking the first reference current according to the determined characteristic of the output from the power amplification circuit, and wherein the determined characteristic is a magnitude of a voltage.
